(19) United States
(12) Patent Application Publication
(10) Pub. No.: US 2014/0035126 A1
(43) Pub. Date: Feb. 6, 2014

(54) SEMICONDUCTOR MANUFACTURING METHOD AND SEMICONDUCTOR STRUCTURE THEREOF

(71) Applicants: Chih-Ming Kuo, Hsinchu County (TW); Lung-Hua Ho, Hsinchu City (TW); Kung-An Lin, Hsinchu City (TW); Sheng-Hiu Chen, Taichung City (TW)

(72) Inventors: Chih-Ming Kuo, Hsinchu County (TW); Lung-Hua Ho, Hsinchu City (TW); Kung-An Lin, Hsinchu City (TW); Sheng-Hiu Chen, Taichung City (TW)

(73) Assignee: CHIPBOND TECHNOLOGY CORPORATION, Hsinchu (TW)

(21) Appl. No.: 13/562,558

(22) Filed: Jul. 31, 2012

(51) Int. Cl. H01L 23/48; H01L 21/768

(52) U.S. Cl. 257/737; 438/613; 257/E23.021; 257/E21.506

(57) ABSTRACT

A semiconductor manufacturing method includes providing a substrate having a metallic layer that includes a first metal layer and a second metal layer, the first metal layer comprises plural base areas and plural first outer lateral areas, the second metal layer comprises plural second base areas and plural second outer lateral areas; forming a first photoresist layer; forming plural bearing portions; removing the first photoresist layer; forming a second photoresist layer; forming plural connection portions, each connection portion comprises a first connection layer and a second connection layer; removing the second photoresist layer to reveal the connection portions and the bearing portions; removing the first outer lateral areas; reflowing the second connection layers to form plural composite bumps; removing the second outer lateral areas to make the first base areas and the second base areas form plural under bump metallurgy layers.

### FIELD OF THE INVENTION

The present invention is generally related to a semiconductor manufacturing method, which particularly relates to the semiconductor manufacturing method for forming a plurality of bumps with protection layers.

### BACKGROUND OF THE INVENTION

A conventional semiconductor package structure makes bumps of a chip electrically coupled with connection pads of a substrate via a plurality of solders. However, since modern mobile device gradually leads a direction of light and small, the spacing between adjacent bumps of the chip decreases as well. In the reflow process, the solders likely overflow toward adjacent bumps and leads to a short phenomenon therefore lowering the yield rate of products.

### SUMMARY

The primary object of the present invention is to provide a semiconductor manufacturing method including the steps of providing a substrate having a surface and a metallic layer formed on the surface, wherein the metallic layer includes a first metal layer and a second metal layer, the first metal layer comprises a plurality of first base areas and a plurality of first outer lateral areas located outside the first base areas, the second metal layer comprises a plurality of second base areas and a plurality of second outer lateral areas located outside the second base areas; forming a first photoresist layer on the metallic layer, wherein the first photoresist layer comprises a plurality of first openings; forming a plurality of bearing portions at the first openings; removing the first photoresist layer to reveal the bearing portions, each bearing portion comprises a bearing surface having a first area and a second area; forming a second photoresist layer on the metallic layer and covering the bearing portions with the second photoresist layer; wherein the second photoresist layer comprises a plurality of second openings for revealing the first areas of the bearing surfaces; forming a plurality of connection portions at the second openings, each connection portion comprises a first connection layer and a second connection layer, the first connection layers cover the first areas of the bearing surfaces, wherein each first connection layer is in connection with each bearing portion and comprises a top surface and a ring surface, and each second connection layer covers the top surface of each first connection layer; removing the second photoresist layer to reveal the connection portions and the bearing portions; removing the first outer lateral areas of the first metal layer to reveal the second outer lateral areas of the second metal layer; reflowing the second connection layers of the connection portions to make the ring surfaces of the first connection layers covered with the second connection layers to form a plurality of composite bumps; removing the second outer lateral areas of the second metal layer to make the first base areas of the first metal layer and the second base areas of the second metal layer form a plurality of under bump metallurgy layers. Since each composite bump possesses the bearing portion, each second connection layer can be constrained at the second area of each bearing surface for raising reliability of electrical connection. Besides, once the composite bumps contain with copper, the second connection layers may prevent the composite bumps from oxidation.

### DESCRIPTION OF THE DRAWINGS

FIG. 1 is a flow chart illustrating a semiconductor manufacturing method in accordance with a preferred embodiment of the present invention.

FIGS. 2A to 2J are cross section diagrams illustrating a semiconductor manufacturing method in accordance with a preferred embodiment of the present invention.

### DETAILED DESCRIPTION OF THE INVENTION

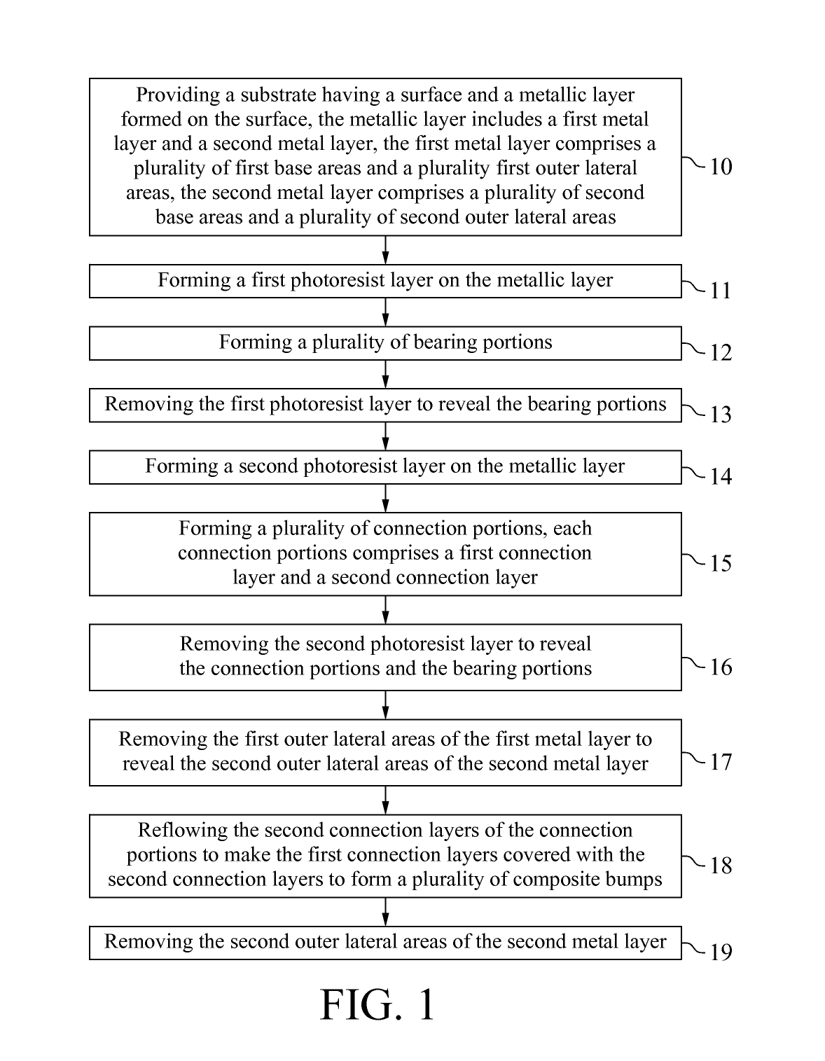

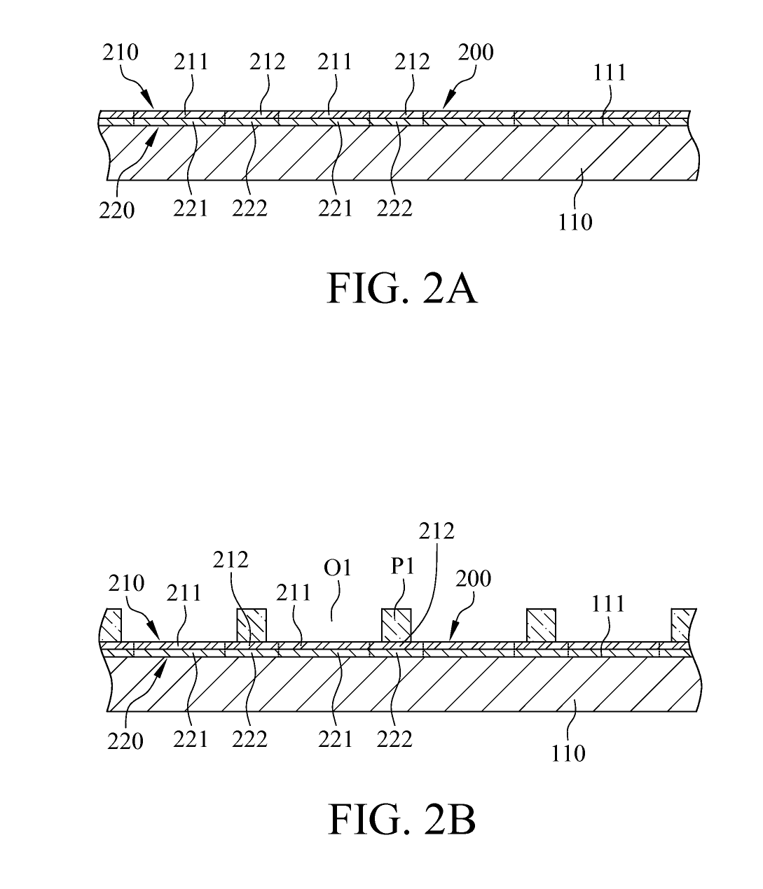

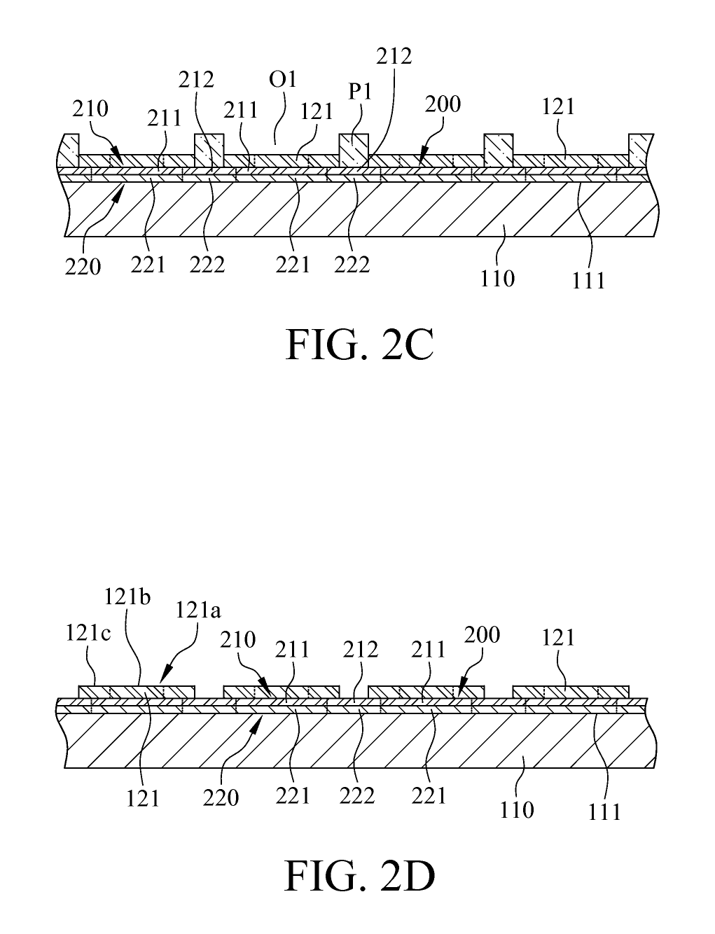

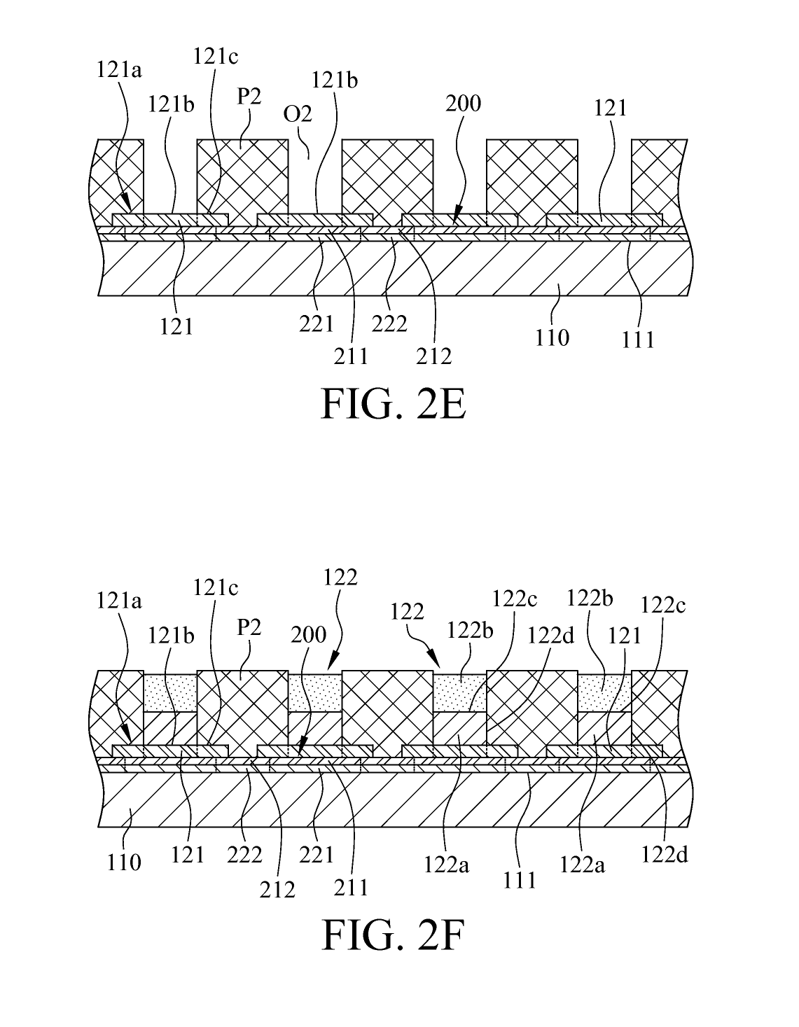

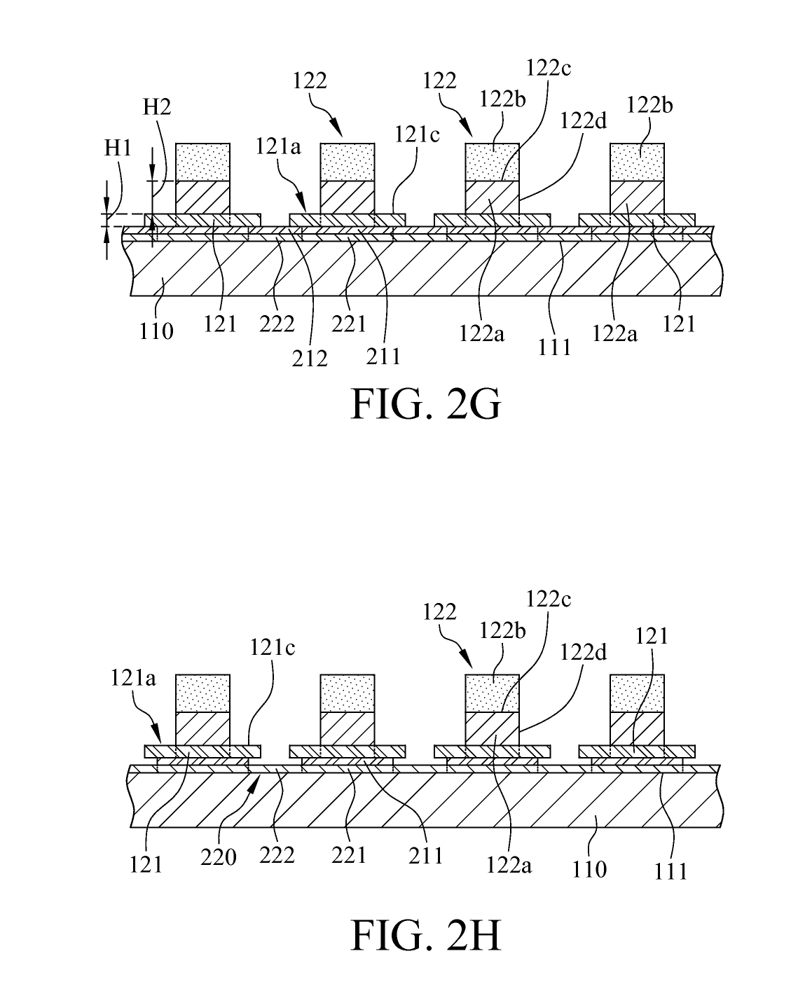

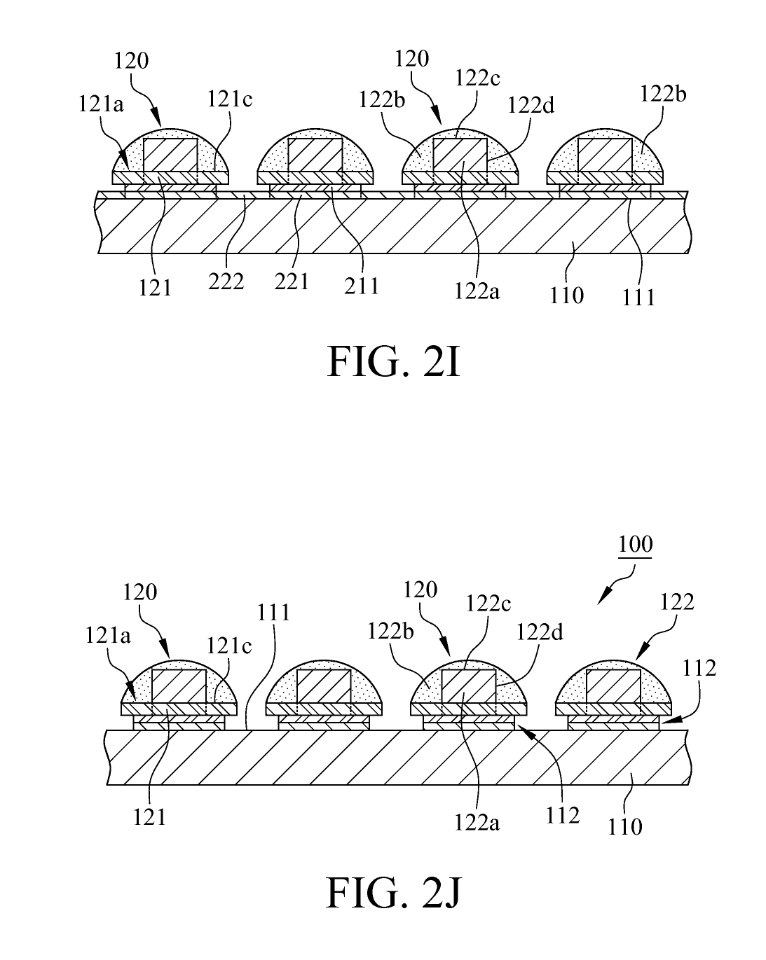

With reference to FIGS. 1 and 2A to 2J, a semiconductor manufacturing method in accordance with a preferred embodiment of the present invention includes the steps as followed. First, referring to step 10 in FIG. 1 and FIG. 2A, providing a substrate 110 having a surface 111 and a metallic layer 200 formed on the surface 111, the metallic layer 200 includes a first metal layer 210 and a second metal layer 220, the first metal layer 210 comprises a plurality of first base areas 211 and a plurality of first outer lateral areas 212 located outside the first base areas 211, the second metal layer 220 comprises a plurality of second base areas 221 and a plurality of second outer lateral areas 222 located outside the second base areas 221; next, referring to step 11 in FIG. 1 and FIG. 2B, forming a first photoresist layer P1 on the metallic layer 200, wherein the first photoresist layer P1 comprises a plurality of first openings O1; thereafter, referring to step 12 in FIG. 1 and FIG. 2C, forming a plurality of bearing portions 121 at the first openings O1, the material of bearing portions 121 is selected from one of gold, nickel and copper; afterwards, referring to step 13 in FIG. 1 and FIG. 2D, removing the first photoresist layer P1 to reveal the bearing portions 121, each bearing portion 121 comprises a bearing surface 121a having a first area 121b and a second area 121c; next, with reference to step 14 in FIG. 1 and FIG. 2E, forming a second photoresist layer P2 on the metallic layer 200 and covering the bearing portions 121 with the second photoresist layer P2, wherein the second photoresist layer P2 comprises a plurality of second openings O2 for revealing the first areas 121b of the bearing surfaces 121a; then, referring to step 15 in FIG. 1 and FIG. 2F, forming a plurality of connection portions 122 at the second openings O2, each connection portion 122 comprises a first connection layer 122a and a second connection layer 122b, the first connection layers 122a cover the first areas 121b of the bearing surfaces 121a, wherein each first connection layer 122a is in connection with each bearing portion 121 and comprises a top surface 122c and a ring surface 122d, and each second connection layer 122b covers the top surface 122c of each first connection layer 122a, in this embodiment, the material of the first connection layers 122a is selected from one of gold, nickel and copper, and the material of the second connection layers 122b is solder; afterwards, referring to step 16 in FIG. 1 and FIG. 2G, removing the second photoresist layer P2 to reveal the connection portions 122 and the bearing portions 121, in this embodiment, each bearing portion 121 comprises a first thickness H1, each first connection layer 122a comprises a second thickness H2 larger than the first thickness H1; thereafter, referring to step 17 in FIG. 1 and FIG. 2H, removing the first outer lateral areas 212 of the first metal layer 210 to reveal the second outer lateral areas 222 of the second metal layer 220; next, referring to step 18 in FIG. 1 and FIG. 21, reflowing the second connection layers 122b of the connection portions 122 to make the ring surfaces 122d of the first connection layers 122a covered with the second connection layers 122b so as to form a plurality of composite bumps 120, wherein each second connection layer 122b is constrained at the second area 121c of each bearing surface 121a; eventually, referring to step 19 in FIG. 1 and FIG. 2J, removing the second outer lateral areas 222 of the second metal layer 220 to make the first base areas 211 of the first metal layer 210 and the second base areas 221 of the second metal layer 220 form a plurality of under bump metallurgy layers 112 therefore forming a semiconductor structure 100, wherein the material of the under bump metallurgy layers 112 is selected from one of titanium/copper, titanium-tungsten/copper or titanium-tungsten/gold. Since each composite bump 120 possesses the bearing portion 121, each second connection layer 122b can be constrained at the second area 121c of each bearing surface 121a for raising reliability of electrical connection. Besides, once the composite bumps 120 contain copper, the second connection layers 122b may prevent the composite bumps 120 from oxidation.

A semiconductor structure 100 of the present invention is illustrated in FIG. 2J. The semiconductor structure 100 at least includes a substrate 110 and a plurality of composite bumps 120. The substrate 110 comprises a surface 111 and a plurality of under bump metallurgy layers 112 formed on the surface 111, and the composite bumps 120 are formed on the under bump metallurgy layers 112. Each composite bump 120 comprises a bearing portion 121 and a connection portion 122, wherein each bearing portion 121 comprises a bearing surface 121a having a first area 121b and a second area 121c. The connection portion 122 comprises a first connection layer 122a and a second connection layer 122b, and each first connection layer 122a covers the first area 121b of each bearing surface 121a and connects with the bearing portion 121. Each first connection layer 122a comprises a top surface 122c and a ring surface 122d, and the second connection layers 122b cover the top surfaces 122c and the ring surfaces 122d of the first connection layers 122a. Preferably, each second connection layer 122b is constrained at the second area 121c of each bearing surface 121a. Each bearing portion 121 comprises a first thickness H1, and each first connection layer 122a comprises a second thickness H2 larger than the first thickness H1. In this embodiment, the material of the under bump metallurgy layers 112 is selected from one of titanium/copper, titanium-tungsten/copper or titanium-tungsten/gold, the material of the bearing portions 121 is selected from one of gold, nickel or copper, the material of the first connection layers 122a is selected from one of gold, nickel or copper, and the material of the second connection layers 122b is solder.

While this invention has been particularly illustrated and described in detail with respect to the preferred embodiments thereof, it will be clearly understood by those skilled in the art that it is not limited to the specific features and describes and various modifications and changes in form and details may be made without departing from the spirit and scope of this invention.

What is claimed is:

1. A semiconductor manufacturing method at least includes:
providing a substrate having a surface and a metallic layer formed on the surface, the metallic layer includes a first metal layer and a second metal layer, the first metal layer comprises a plurality of first base areas and a plurality of first outer lateral areas located outside the first base areas, the second metal layer comprises a plurality of second base areas and a plurality of second outer lateral areas located outside the second base areas;
forming a first photoresist layer on the metallic layer, wherein the first photoresist layer comprises a plurality of first openings;
forming a plurality of bearing portions at the first openings;
removing the first photoresist layer to reveal the bearing portions, wherein each bearing portion comprises a bearing surface having a first area and a second area;
forming a second photoresist layer on the metallic layer and covering the bearing portions with the second photoresist layer, wherein the second photoresist layer comprises a plurality of second openings for revealing the first areas of the bearing surfaces;
forming a plurality of connection portions at the second openings, each connection portion comprises a first connection layer and a second connection layer, the first connection layers cover the first areas of the bearing surfaces, wherein each first connection layer is in connection with each bearing portion and comprises a top surface and a ring surface, and the top surface of each first connection layer is covered with each second connection layer;
removing the second photoresist layer to reveal the connection portions and the bearing portions;
removing the first outer lateral areas of the first metal layer to reveal the second outer lateral areas of the second metal layer;
reflowing the second connection layers of the connection portions to make the ring surfaces of the first connection layers covered with the second connection layers to form a plurality of composite bumps; and
removing the second outer lateral areas of the second metal layer to make the first base areas of the first metal layer and the second base areas of the second metal layer forming a plurality of under bump metallurgy layers.

2. The semiconductor manufacturing method in accordance with claim 1, wherein each second connection layer is constrained at the second area of each bearing surface.

3. The semiconductor manufacturing method in accordance with claim 1, wherein each bearing portion comprises a first thickness, each first connection layer comprises a second thickness larger than the first thickness.

4. The semiconductor manufacturing method in accordance with claim 1, wherein the material of the bearing portions is selected from one of gold, nickel or copper.

5. The semiconductor manufacturing method in accordance with claim 1, wherein the material of the first connection portions is selected from one of gold, nickel or copper.

6. The semiconductor manufacturing method in accordance with claim 1, wherein the material of the under bump metallurgy layers is selected from one of titanium/copper, titanium-tungsten/copper or titanium-tungsten/gold.

7. A semiconductor structure at least includes:
a substrate having a surface and a plurality of under bump metallurgy layers formed on the surface; and
a plurality of composite bumps formed on the under bump metallurgy layers, each composite bump comprises a bearing portion and a connection portion, each bearing portion comprises a bearing surface having a first area and a second area, each connection portion comprises a first connection layer and a second connection layer, wherein each first connection layer covers the first area of each bearing surface and connects with the bearing portion, each first connection layer comprises a top surface and a ring surface, the second connection layers cover the top surfaces and the ring surfaces of the first connection layers.

8. The semiconductor structure in accordance with claim 7, wherein each second connection layer is constrained at the second area of each bearing surface.

9. The semiconductor structure in accordance with claim 7, wherein each bearing portion comprises a first thickness, each first connection layer comprises a second thickness larger than the first thickness.

10. The semiconductor structure in accordance with claim 7, wherein the material of the bearing portions is selected from one of gold, nickel or copper.

11. The semiconductor structure in accordance with claim 7, wherein the material of the first connection portions is selected from one of gold, nickel or copper.

12. The semiconductor structure in accordance with claim 7, wherein the material of the under bump metallurgy layers is selected form one of titanium/copper, titanium-tungsten/copper or titanium-tungsten/gold.
